(19) United States
(12) Patent Application Publication
(10) Pub. No.: US 2015/0142347 A1
(43) Pub. Date: May 21, 2015

(54) Solar Energy Disaggregation Techniques for Whole-House Energy Consumption Data

(71) Applicants: Rahul Mohan, Sunnyvale, CA (US); Hsien-Teng Cheng, San Jose, CA (US); Abhay Gupta, Cupertino, CA (US); Ye He, Mountain View, CA (US); Vivek Garud, Cupertino, CA (US)

(72) Inventors: Rahul Mohan, Sunnyvale, CA (US); Hsien-Teng Cheng, San Jose, CA (US); Abhay Gupta, Cupertino, CA (US); Ye He, Mountain View, CA (US); Vivek Garud, Cupertino, CA (US)

(21) Appl. No.: 14/543,805

(22) Filed: Nov. 17, 2014

Related U.S. Application Data
(60) Provisional application No. 61/904,608, filed on Nov. 15, 2013.

(51) Int. Cl. G01R 21/133; G01W 1/10

(52) U.S. Cl. CPC G01R 21/133; G01W 1/10
USPC 702/60

(57) ABSTRACT

Systems and methods of the present invention are directed to disaggregating the contribution of solar panels from a whole house energy profile. Methods of disaggregating energy produced by solar panels from low frequency whole-house energy consumption data for a specific house, may include steps of: predicting solar energy generation for the specific house by estimating a solar capacity of the solar panels, predicting solar intensity associated with the specific house, and multiplying estimated solar capacity with predicted solar intensity; and subtracting the predicted solar energy generation from the low frequency whole house energy consumption data, thereby disaggregating the contribution of energy produced by the solar panels. Computerized systems of the same may apply machine learning models such as radial basis function, support vector, or neural network machines.

### RELATED APPLICATIONS

This application claims priority to U.S. Provisional Patent Application No. 61/904,608 filed on 15 Nov. 2014, which is incorporated herein in its entirety.

### BACKGROUND

Renewable energy sources, such as but not limited to solar energy, may offer many environmental advantages over fossil fuels for electricity generation. However, the energy produced by such renewable sources may fluctuate with changing weather conditions. Electric utility companies may desire accurate forecasts of renewable energy production in order to have the right balance of energy sources (e.g., renewable and fossil fuels) available. Errors in the forecast may lead to utility expenses ranging from excess fuel consumption to emergency purchases of electricity from neighboring utilities.

Currently, a significant amount of utilities may only be able to obtain net power readings from a home, which may comprise electrical usage consumption minus production from the solar panels. However, utilities are generally unable to differentiate solar production from consumption, and may therefore not know how much electricity to put into the grid without facing unnecessary costs.

An accurate prediction of solar output may be advantageous or necessary to accurately perform energy disaggregation techniques and inform a consumer of the customer's actual energy usage. However, prior art systems and methods of predicting solar contribution without the use of onsite meters or measuring devices has been generally ineffective and often fails to provide sufficient accuracy and predictability to support energy disaggregation techniques. Accordingly, systems and methods that can accurately and predictably account for the contribution of energy from solar panels are desirable.

### SUMMARY OF THE INVENTION

Aspects of the invention may include a method for disaggregating energy produced by solar panels from low frequency whole-house energy consumption data for a specific house, comprising: predicting solar energy generation for the specific house; and subtracting the predicted solar energy generation from the low frequency whole house energy consumption data, thereby disaggregating the contribution of energy produced by the solar panels.

Other aspects of the invention may include a method for disaggregating energy produced by solar panels from low frequency whole-house energy consumption data for a specific house, comprising: predicting solar energy generation for the specific house, comprising: estimating a solar capacity of the solar panels, comprising: solving the equation SolarCapacity=−1*(Baseload−min(DayNet)), wherein: Baseload is equal to a lowest 20^{th} percentile of net power used by the specific home when there is no or negligible solar generation; and DayNet is equal to the appliance consumption minus any solar generation of the specific house from sunrise to sunset; predicting solar intensity associated with the specific house, comprising: preprocessing the low frequency whole-house energy consumption data to clean the data and remove outliers; normalizing data; applying a machine learning model to generate a non-linear model of solar intensity; multiplying estimated solar capacity with predicted solar intensity; and subtracting the predicted solar energy generation from the low frequency whole house energy consumption data, thereby disaggregating the contribution of energy produced by the solar panels.

Additional aspects of the invention may include a computerized system for disaggregating energy produced by solar panels from low frequency whole-house energy consumption data for a specific house received from a Smart Meter, comprising: a prediction module configured to predict solar energy generation for the specific house; and a processing module configured to subtract the predicted solar energy generation from the low frequency whole house energy consumption data, thereby disaggregating the contribution of energy produced by the solar panels.

Additional aspects of the invention may include a method for appliance level disaggregating of high frequency whole-house energy consumption data for a specific house, wherein the high frequency whole-house energy consumption data for the specific house includes energy produced by solar panels, the method comprising: identifying correlations between weather conditions and usage spikes; determining weather spikes caused by weather; identify appliance features; determine appliance usage spikes caused by appliance usage; provide weather spikes and appliance usage spikes to a classification model; receive at the classification model the high frequency whole-house energy consumption data for the specific house; apply the classification model to the high frequency whole-house energy consumption data for the specific house; remove weather spikes from the high frequency whole-house energy consumption data for the specific house.

These and other aspects will become apparent from the following description of the invention taken in conjunction with the following drawings, although variations and modifications may be effected without departing from the scope of the novel concepts of the invention.

### BRIEF DESCRIPTION OF THE DRAWINGS

The present invention can be more fully understood by reading the following detailed description together with the accompanying drawings, in which like reference indicators are used to designate like elements. The accompanying figures depict certain illustrative embodiments and may aid in understanding the following detailed description. Before any embodiment of the invention is explained in detail, it is to be understood that the invention is not limited in its application to the details of construction and the arrangements of components set forth in the following description or illustrated in the drawings. The embodiments depicted are to be understood as exemplary and in no way limiting of the overall scope of the invention. Also, it is to be understood that the phraseology and terminology used herein is for the purpose of description and should not be regarded as limiting. The detailed description will make reference to the following figures, in which:

FIG. 1 depicts an example of a net power in accordance with some embodiments of the present invention.

FIG. 2 depicts an example of a solar power signal for three (3) days, in accordance with some embodiments of the present invention.

FIG. 3 illustrates an exemplary prediction algorithm in accordance with some embodiments of the present invention.

FIG. 4 illustrates an exemplary training algorithm in accordance with some embodiments of the present invention.

FIG. 5 depicts an exemplary plot illustrating a predicted solar power and a ground truth solar power, in accordance with some embodiments of the present invention.

FIG. 6 illustrates an exemplary process for disaggregating solar contribution from a whole house profile based on high frequency data, in accordance with some embodiments of the present invention.

FIG. 7 illustrates an exemplary screen-capture from a graphical user interface in accordance with some embodiments of the present invention.

FIG. 8 illustrates an exemplary screen-capture from a graphical user interface in accordance with some embodiments of the present invention.

Before any embodiment of the invention is explained in detail, it is to be understood that the present invention is not limited in its application to the details of construction and the arrangements of components set forth in the following description or illustrated in the drawings. The present invention is capable of other embodiments and of being practiced or being carried out in various ways. Also, it is to be understood that the phraseology and terminology used herein is for the purpose of description and should not be regarded as limiting.

### DETAILED DESCRIPTION OF THE INVENTION

The matters exemplified in this description are provided to assist in a comprehensive understanding of various exemplary embodiments disclosed with reference to the accompanying figures. Accordingly, those of ordinary skill in the art will recognize that various changes and modifications of the exemplary embodiments described herein can be made without departing from the spirit and scope of the claimed invention. Descriptions of well-known functions and constructions are omitted for clarity and conciseness. Moreover, as used herein, the singular may be interpreted in the plural, and alternately, any term in the plural may be interpreted to be in the singular.

In accordance with some embodiments of the present invention, solar output may be predicted for unseen homes (and therefore, homes where solar contribution is not directly measured), by using training data. Training data may provide a predictive model regardless of the location from which the training data was obtained, and therefore data from different locations in both the United States and around the world can be utilized to provide more accurate predictions.

In accordance with some embodiments of the present invention, a solar capacity for a specific home may be derived by examining the historical net power signature of the specific home. Such techniques may not require the installation of any hardware (for example, CT clamps), because the solar capacity may be derived as a function of the square footage and orientation of the solar panels.

Techniques for energy disaggregation may be determined and/or impacted by the type of data and/or how the data is obtained or accessed. For example, data types may include power signals, or meteorological data or conditions. Power signals may be obtained in low frequency or high frequency samples.

Low frequency data may be sampled—for example—hourly, while high or higher frequency data may be sampled—for example—each minute. Meteorological data or conditions may include information such as, but not limited to, (i) skycover or cloud cover (which may be set forth as a percentage or ratio of cover to clear sky); (ii) temperature; (iii) wind-speed; (iv) dew point; and (v) sunrise/sunset times.

Data may be obtained and/or accessed in various manners. For example, a current clamp (CT clamp) may be utilized. The use of two (2) CT clamps may generally be used, with one CT claim positioned at or proximate to the net meter (which may indicate net power draw for the house), and a second CT clamp positioned at or proximate to the solar system (which may indicate power captured and contributed by the solar system). Alternatively, energy usage data may be obtained from Green Button (an industry effort to provide transparent energy usage data, which is generally provided in hourly intervals); from Smart Meters—for example using a Smart Meter Home Area Network channel; from a Zigbee connection (which, utilizes data captured by the Zigbee alliance that sets forth energy consumption data); or from a direct connection to a solar company, for example through the use of an application programming interface (API) that connects with a solar company to obtain energy data (either net usage or solar contribution).

Note that the methods in accordance with some embodiments of the present invention may utilize data or information that may retrieved from energy meters deployed in homes. For example, total energy consumption data may be retrieved through at least two mechanisms. First, systems in accordance with the present invention may be in selective communication with a utility, for example, by way of a utility portal. Accordingly, total energy consumption data may be retrieved directly from the utility.

Second, data may be obtained directly from the home. This may be accomplished, for example, through the use of a gateway device that may be positioned between the house electric meter and the systems of the present invention. Such devices may include, but are not limited to a Zigbee gateway that may connect with a digital Smart Meter, fetch total energy consumption and provide information regarding real-time or near real-time energy consumption; an infrared or visible LED sensor, which may be physically attached to a meter and detect energy consumption by counting pulses emitted by the LED (as visible light or infrared); or a CT clamp, as discussed above.

Regardless of the source of the information, data regarding total energy consumption may be sent to processors, servers, and data stores of systems in accordance with some embodiments of the present invention for subsequent processing and analysis.

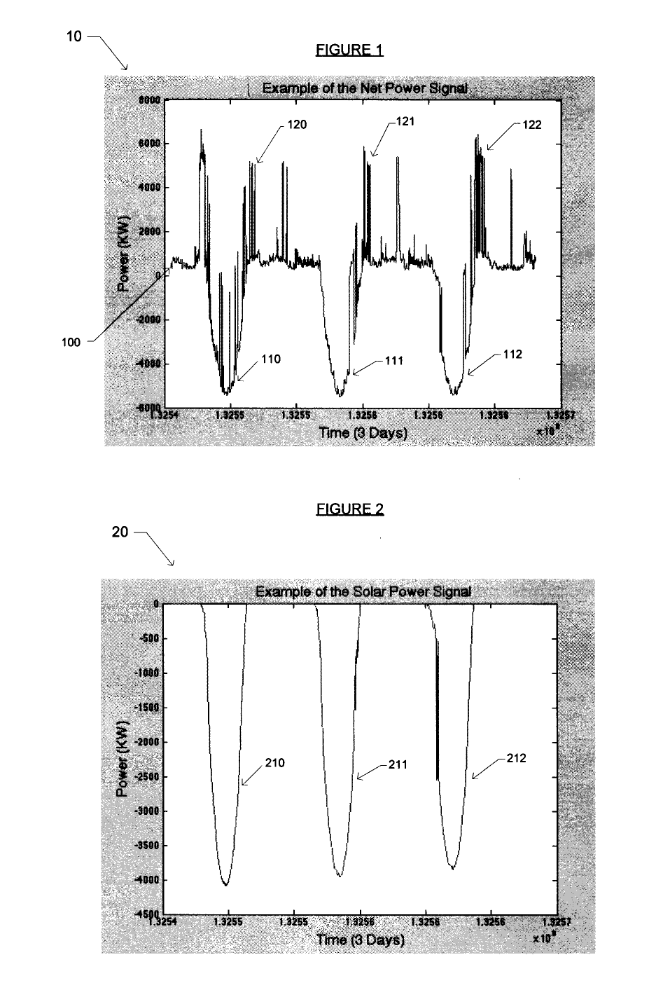

With reference to FIG. 1, a graph 10 showing an exemplary power signature 100 over a three (3) day period is illustrated. In general, note that the derivative of the net power curve may typically increase negatively from sunrise to approximately 12:00 PM (noon), where it may zero out for a period of time before becoming positive as the time approaches sunset. This results from the addition of power from the solar panels during daylight hours.

It can be seen from FIG. 1 that each day there is a time period when the net power signal is generally negative (illustrated by reference numerals 110, 111, 112), which reflects the addition of solar energy. Note that there may be some variations during this period of time as (i) appliances may be used during this time period; and/or (ii) weather conditions, such as cloud cover, may impact the energy production of the solar panels.

It may also be evident from FIG. 1 that there is an increase in the netpower signal following production of the solar panels (as illustrated by reference numerals 120, 121, 122). This may be associated with increased energy usage when the solar panels are not producing energy—which is typically in the evening/early night hours when the occupants are generally awake and consuming energy through appliance usage, etc.

With reference to FIG. 2, an example of a solar power signal 20 for three (3) days, in accordance with some embodiments of the present invention is presented. Note that there may be one major curve per day from sunrise to sunset (though this may be impacted by weather patterns, etc.). It can be seen that each day presents a negative power signal (as illustrated by reference numerals 210, 211, 212), where the peak of negative energy signal is typically at or around noon. Note that such solar power signal curves may be obtained by using a radial basis function model and fitting a Gaussian curve to data determined to be associated with the solar panels.

As noted above, different techniques may be utilized if the energy data received is low frequency or high frequency data. Each will be discussed in turn below.

Techniques Used for Low Frequency Consumption Data.

When using low frequency whole-house energy consumption data, the energy contribution of solar panels must be determined and disaggregated. Such disaggregation may be based upon, among other factors, meteorological data. In general, such determination may be made by (i) estimating the solar panel capacity for a specific home; (ii) predicting the solar intensity of the specific home; (iii) based upon the capacity and intensity, predicting solar generation; and (iv) disaggregating the solar energy produced from the low frequency whole-house energy consumption data. Each of these factors will be discussed below. With reference to FIG. 3 graphically depicts an exemplary training algorithm 30 in accordance with some embodiments of the present invention that may assist in determining the amount of solar generation. In general, process 30 may comprise three (3) components. First, at 310 solar intensity may be determined, which may be based at least in part upon a regression model trained with weather data. Second, at 320 solar capacity of solar panels may be determined, as set forth in greater detail below. Third, at 330 solar generation may be determined based at least in part upon the determined solar intensity and the solar capacity. In this manner, solar generation may be determined for a specific house based upon data that is not included in the whole-house energy profile.

Solar Panel Capacity Estimation. Solar panel capacity may be defined as the maximum output of solar panel in kilowatts (kW). This capacity may generally be estimated by examining historical net power signatures. Based upon historical net power signatures, Solar Capacity may be determined by the following equation:

SolarCapacity=−1×(Baseload−min(DayNet))

Where “Baseload” equals the lower 20^{th} percentile of net power used by a home during the night (i.e., when there is no or negligible solar contribution), and “DayNet” equals the net power from sunrise to sunset (i.e., appliance consumption minus solar generation).

Note that the signal of the solar panel is always negative since it produces energy. Solar power is generated the most during the day causing the net power signal to become negative. The minimum of net during the day cannot be deemed alone to be the solar capacity, since there are generally other appliances being used during the day which may cause the net power to be generally higher than the solar power generated. Accordingly, a baseload may be calculated as the lower 20^{th} percentile of the net power during the night when solar power is not present. This lower 20^{th} percentile represents that twenty (20) percent of the appliances active during the day are also active during the night. The use of the 20^{th} percentile has been selected because such percentile produces greater accuracy when comparing ground-truth solar capacity and estimated capacity. The 20^{th} percentile was identified through a grid search, although it is contemplated that other percentiles may be utilized without deviating from the present invention.

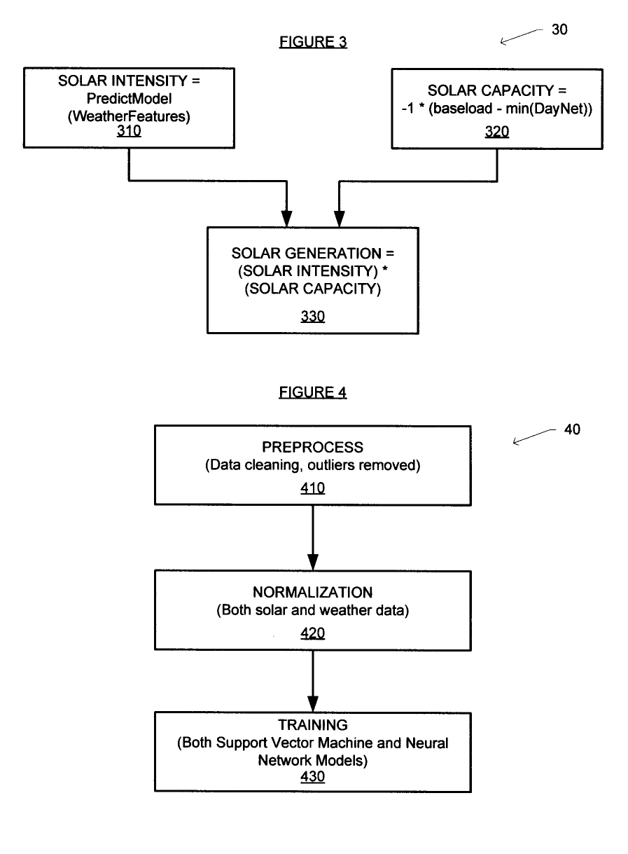

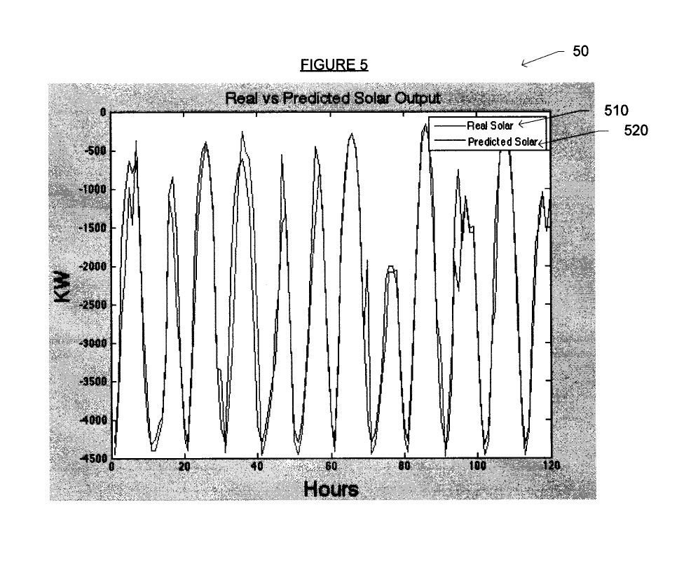

Solar Intensity Prediction. Next, a regression model may be trained with weather data and the number of hours from sunrise to sunset as one or more independent variables, and solar intensity as the dependent variable. With reference to FIG. 4, a flowchart 40 depicting a training algorithm in accordance with some embodiments of the present invention may be seen. Flowchart 40 may generally comprise three (3) steps. At 410 the data may undergo a preprocessing, where such data may be generally cleaned and outliers may be removed.

At 420 both solar data and weather data may be normalized, which may be accomplished using the ground truth data of solar generation, as may be collected (for example) by a circuit level clamp or sensor. In general, solar intensity may be seen as the normalized version of solar generation, and may be stated in the range from 0 to 1. Normalization of the dependent variable may be desirable when using a regression model, because it generally permits or allows the model to be easily trained. In accordance with some embodiments of the present invention, a radial basis function (RBF) support vector machine combined with RBF neural networks may be used. RBF support vector machine and RBF neural networks are machine learning algorithms that may create highly complex non-linear models.

While various other machine learning models and algorithms may be utilized without deviating from the present invention, RBF models may be selected because such models strive to fit Gaussian curves to the data, and is accordingly suited for Gaussian-shaped solar panel generation curves. Such Gaussian-shaped solar panel generation curves may be seen in FIG. 2.

At 430—and as discussed above—a support vector machine and neural network model may be applied. Machine learning models may then be optimized in any number of ways as known in the art. For example, optimization may be performed by obtaining optimal model parameters, 10-fold cross validation, and regularization. Support vector machines and neural networks (as discussed above) generally provide more accurate results when a large amount of training data is available. Solar intensity testing prediction may therefore be more obtained with an accuracy higher than the reported accuracies from previous work, despite training and testing on different homes and different parts of the world.

Solar Generation Prediction. Based upon the earlier results of the estimated capacity and determined solar intensity prediction, solar generation prediction may be obtained by multiplying the estimated capacity with the solar intensity prediction. The prediction is now transformed back to the KW range.

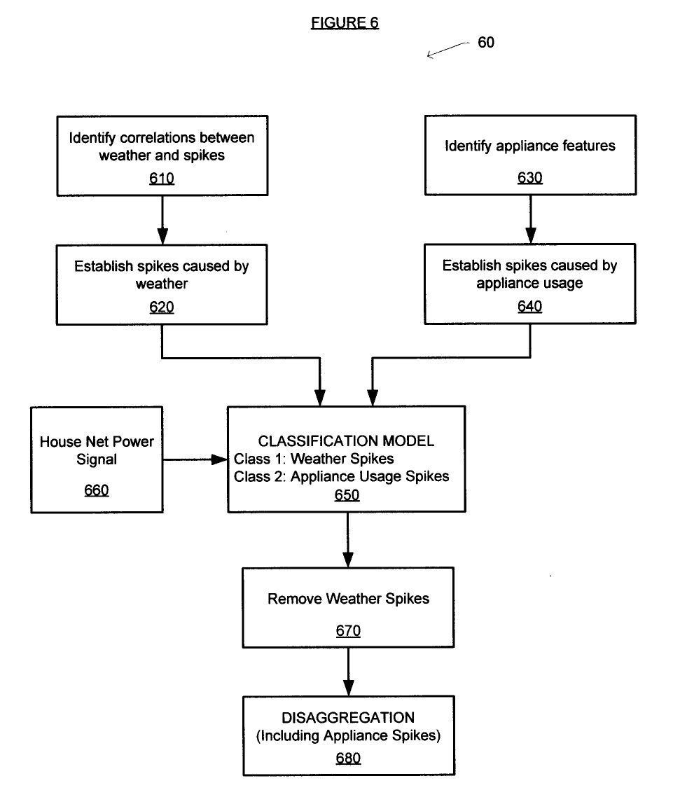

With reference to FIG. 5, an example of a predicted solar panel generation and ground truth generation for a specific home, in accordance with some embodiments of the present invention is depicted at 50. It can be seen that real solar output 510 very closely tracks predicted solar output 520.

Solar Energy Disaggregation. Finally, predicted solar generation may be subtracted from the net power of the specific home, thereby disaggregating the contribution of solar energy from the low frequency whole-house energy consumption data.

Techniques Used for High Frequency Consumption Data

While high frequency data may be useful in providing more accurate energy predictions, high frequency energy consumption data may include an increase in noise, and may be more difficult to correlate meteorological data (which is generally very low resolution) with such high frequency data.

Solar Signal and Appliance Signal Differentiation. With high frequency data sampled at the one minute level, solar power may be quite noisy. For example, the curve of solar power contribution generated for an exemplary day may include several spikes (for example, due to constantly changing meteorological conditions such as cloud cover). Such spikes may not be merely smoothed, because such spikes may be caused by weather fluctuations or may be caused by an appliance being used at the same time. Accordingly, techniques may be desirable that differentiate spikes from solar signals caused by weather from those caused by appliance usage.

With reference to FIG. 6, an exemplary process 60 for disaggregating solar contribution from a whole house profile based on high frequency data, in accordance with some embodiments of the present invention will now be discussed. In general, techniques of differentiating such spikes may comprise: (i) identifying correlations between weather and spikes in the data; (ii) establishing spikes caused by weather; (iii) determining features used in appliance usage by using waveform characteristics and transitions; (iv) training a classification model with two (2) classes: weather caused spikes and appliance usage spikes; and (v) performing disaggregation only on spikes that are not determined to be caused by weather.

With continued reference to FIG. 6, process 60 may generally comprise the determination of weather spikes and appliance spikes. Specifically, at 610 correlations between weather and spikes may be identified. Based at least in part on such information, at 620 spikes caused by weather may be established. Similarly, at 630 correlations between features of appliance usage and spikes may be identified. Based at least in part on such information, at 640 spikes caused by appliance usage may be established. Information regarding weather spikes 620 and appliance spikes 640 may be provided to a classification model 650.

Classification model 650 may also receive information 660 comprising the net power signal of a house. Based at least in part upon the weather spike and appliance spike information (620, 640), the classification model may create two classes: the first being weather spikes, and the second being appliance spikes. At 670 the weather spikes may be removed, leaving spikes caused by appliances. The spikes caused by appliances may be included in the power signal upon which disaggregation techniques may be applied. In this manner, accurate appliance level disaggregation may be conducted, even with the fluctuating input provided by solar panels.

Solar Energy Prediction and Disaggregation. Weather features may then be extrapolated from data sampled hourly or by the minute. The solar energy prediction algorithm and models discussed above with low frequency energy data may then be used to accurately predict solar energy contribution, which may then be deducted from the net power in order to obtain solar energy disaggregation.

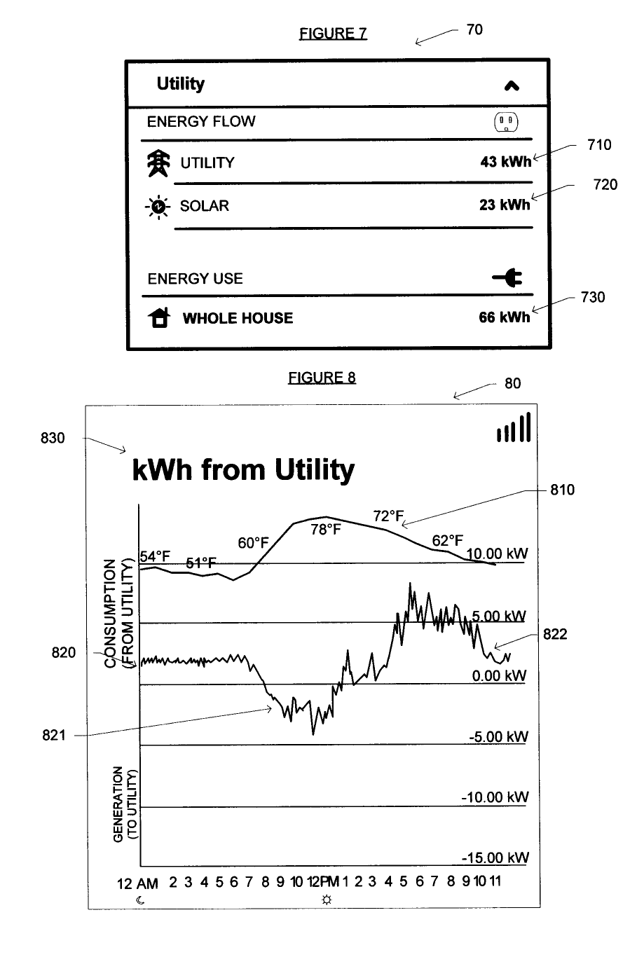

With reference to FIGS. 7-8, a graphical user interface in accordance with some embodiments of the present invention will now be discussed. FIG. 7 sets forth a display 70, which informs a user of how much energy from a utility has been consumed 710, how much energy from renewable resources has been consumed 720, and the total energy use of the whole house 730.

Such information can be broken down in more detail. With reference to FIG. 8, the amount of energy consumed from a utility may be illustrated graphically, with a temperature trend 810, and a graphical depiction of the amount of energy used from the utility at 820. Note that energy usage falls to negative at 821—a time when the solar panels were producing more energy than was being used (and accordingly such energy was provided to the utility), and times when the energy usage from the utility was higher 822. The total amount of energy utilized from the utility may again be presented 830, in order to illustrate to the user the total amount of usage that is being purchased.

In other words, 820 may indicate the net energy flow (including both home consumption and solar generation) received from meter, solar generation estimation may also be illustrated with weather information overlay 810. The user can be exposed to this chart by web, mobile or other dashboard platform and abnormal solar generation (extremely high or low) can be informed to the user by emails, text message, mobile notifications or any other notifying means.

It will be understood that the specific embodiments of the present invention shown and described herein are exemplary only. Numerous variations, changes, substitutions and equivalents will now occur to those skilled in the art without departing from the spirit and scope of the invention.

For example, the present invention predominantly discusses solar energy. However, similar techniques may be applied to other renewable energy sources, such as wind. In a wind-based scenario, the intensity, capacity, and total generation of the windmill (or other device) may be determined in a similar fashion. Accordingly, it is intended that all subject matter described herein and shown in the accompanying drawings be regarded as illustrative only, and not in a limiting sense.

What is claimed is:

1. A method for disaggregating energy produced by solar panels from low frequency whole-house energy consumption data for a specific house, comprising:
predicting solar energy generation for the specific house; and
subtracting the predicted solar energy generation from the low frequency whole house energy consumption data, thereby disaggregating the contribution of energy produced by the solar panels.

2. The method of claim 1, wherein predicting solar energy generation for the specific house comprises:
estimating a solar capacity of the solar panels;
predicting solar intensity associated with the specific house; and
multiplying estimated solar capacity with predicted solar intensity.

3. The method of claim 2, wherein capacity of the solar panels is the maximum output of the solar panels in kilowatts and is determined based at least in part on historical net power signatures.

4. The method of claim 3, wherein the historical net power signatures are from houses other than the specific house.

5. The method of claim 2, wherein estimating a capacity of the solar panels comprises solving the equation SolarCapacity=−1*(Baseload−min(DayNet)), wherein:
Baseload is equal to a lowest 20^{th} percentile of net power used by the specific home when there is no or negligible solar generation; and
DayNet is equal to the net power of the specific house from sunrise to sunset.

6. The method of claim 5, wherein the net power of the specific house from sunrise to sunset is representative of appliance consumption minus any solar generation.

7. The method of claim 2, wherein predicting solar intensity associated with the specific house comprises:
preprocessing the low frequency whole-house energy consumption data to clean the data and remove outliers; and
normalizing data.

8. The method of claim 7, further comprising applying a machine learning model to generate a non-linear model of solar intensity.

9. The method of claim 8, wherein the machine learning model is selected from the group consisting of a radial basis function (RBF) machine, a support vector machine, and/or a neural network.

10. The method of claim 8, further comprising fitting a Gaussian curve to determined data.

11. A method for disaggregating energy produced by solar panels from low frequency whole-house energy consumption data for a specific house, comprising:
predicting solar energy generation for the specific house, comprising:
estimating a solar capacity of the solar panels, comprising:
solving the equation SolarCapacity=−1*(Baseload−min(DayNet)), wherein:
Baseload is equal to a lowest 20^{th} percentile of net power used by the specific home when there is no or negligible solar generation; and
DayNet is equal to the appliance consumption minus any solar generation of the specific house from sunrise to sunset;
predicting solar intensity associated with the specific house, comprising:
preprocessing the low frequency whole-house energy consumption data to clean the data and remove outliers;
normalizing data; and
applying a machine learning model to generate a non-linear model of solar intensity; and
multiplying estimated solar capacity with predicted solar intensity; and
subtracting the predicted solar energy generation from the low frequency whole house energy consumption data, thereby disaggregating the contribution of energy produced by the solar panels.

12. A computerized system for disaggregating energy produced by solar panels from low frequency whole-house energy consumption data for a specific house received from a Smart Meter, comprising:
a prediction module configured to predict solar energy generation for the specific house; and
a processing module configured to subtract the predicted solar energy generation from the low frequency whole house energy consumption data, thereby disaggregating the contribution of energy produced by the solar panels.

13. The system of claim 12, wherein the prediction module receives as an input an estimated solar capacity of the solar panels, predicts a solar intensity associated with the specific house, and predicts solar energy generation for the specific house by multiplying estimated solar capacity with predicted solar intensity.

14. The system of claim 13, wherein the estimated solar capacity of the solar panels is determined based at least in part upon the equation SolarCapacity=−1*(Baseload−min(DayNet)), wherein:
Baseload is equal to a lowest 20^{th} percentile of net power used by the specific home when there is no or negligible solar generation, the net power based at least in part on the low frequency whole-house energy consumption data for the specific house received from the Smart Meter; and
DayNet is equal to the appliance consumption minus any solar generation of the specific house from sunrise to sunset, based at least in part the low frequency whole-house energy consumption data for the specific house received from the Smart Meter.

15. The system of claim 13, wherein the solar intensity is predicted by the prediction module by:
preprocessing the low frequency whole-house energy consumption data for the specific house received from the Smart Meter to clean the data and remove outliers;
normalizing the low frequency whole-house energy consumption data for the specific house received from the Smart Meter; and
applying a machine learning model to generate a non-linear model of solar intensity.

16. The system of claim 15, wherein the machine learning model is selected from the group consisting of a radial basis function (RBF) machine, a support vector machine, and/or a neural network.

17. The system of claim 16, wherein the machine learning model is trained using data that is not from the specific house.

18. A method for appliance level disaggregating of high frequency whole-house energy consumption data for a specific house, wherein the high frequency whole-house energy consumption data for the specific house includes energy produced by solar panels, the method comprising:
identifying correlations between weather conditions and usage spikes;
determining weather spikes caused by weather;
identify appliance features;
determine appliance usage spikes caused by appliance usage;
provide weather spikes and appliance usage spikes to a classification model;
receive at the classification model the high frequency whole-house energy consumption data for the specific house;
apply the classification model to the high frequency whole-house energy consumption data for the specific house;
remove weather spikes from the high frequency whole-house energy consumption data for the specific house.

19. The method of claim 18, wherein:
the step of determining weather spikes caused by weather comprises analyzing data from houses other than the specific house; and
the step of identifying appliance features comprises analyzing data from houses other than the specific house.
